(19) United States
(12) Patent Application Publication
(10) Pub. No.: US 2022/0049905 A1
(43) Pub. Date: Feb. 17, 2022

(54) OSCILLATING HEAT PIPE CHANNEL ARCHITECTURE

(71) Applicant: ThermAvant Technologies, LLC, Columbia, MO (US)

(72) Inventors: Daniel A. Pounds, Columbia, MO (US); Joe Boswell, San Francisco, CA (US); Brian Adams, Columbia, MO (US); Benjamin Alexander, Columbia, MO (US); Joshua Schorp, Columbia, MO (US)

(21) Appl. No.: 17/404,772

(22) Filed: Aug. 17, 2021

Related U.S. Application Data
(60) Provisional application No. 63/066,338, filed on Aug. 17, 2020.

(51) Int. Cl. F28D 15/02; F28F 13/10

(52) U.S. Cl. CPC F28D 15/0275; F28D 15/04; F28D 15/0233; F28F 13/10

(57) ABSTRACT

A monolithic oscillating heat pipe (OHP) device comprising a monolithic body and an oscillating heat pipe (OHP) circuit integrally formed within the body. The OHP circuit is structured and operable to isothermally spread throughout the body heat from a heat source disposed on a heat source portion of the body and in thermally conductive contact with a portion of the OHP circuit. The monolithic OHP device further comprising a pumped fluid (PF) circuit integrally formed within the body and in thermally conductive contact with at least portion of the OHP circuit internally within the body. The PF circuit is structured and operable to remove heat from the portion of the OHP circuit in which the PF circuit is in thermally conductive contact with.

### CROSS-REFERENCE TO RELATED APPLICATIONS

This application claims the benefit of U.S. Provisional Application No. 63/066,338, filed on Aug. 17, 2020, the disclosure of which is incorporated herein by reference in its entirety.

### GOVERNMENT RIGHTS

This invention was made with government support under contract number 82NSSC19C0206 awarded by NASA. The government has certain rights in the invention.

### FIELD

The present teachings relate to various architectures and designs of oscillating heat pipe channels within an oscillating heat pipe device (e.g., an OHP panel) for improving thermal efficiency with regard to the dispersion of thermal energy throughout the OHP device.

### BACKGROUND

The statements in this section merely provide background information related to the present disclosure and may not constitute prior art.

Oscillating heat pipes (OHPs) are often employed in applications where pure conduction, natural convection or radiation are insufficient to maintain the temperature of one or more heat source (e.g., electronics) at a low enough temperature to promote long term reliability. OHPs are passive heat transport devices that are often able to transport heat 100's to 1,000's times more efficiently than solid heat conductors. An OHP device is often used to disperse heat from a heat source to a heat sink where the heat source and the heat sink are of different sizes and/or heat flux. The OHP device provides the thermal link between the heat source and the heat sink with minimal temp rise between the two.

With the extremely high conductance levels achievable with oscillating heat pipe (OHP) devices in certain circumstances, it is often the case that thermal gradients across thermal interfaces between the OHP device and the heat sink exceed the thermal gradients within the OHP itself, or at least are comparable. Additionally, it is sometimes difficult to get a strong condenser interaction between the OHP device and the heat sink due to required edge cooling limiting the number of OHP channels which are being directly cooled. This is particularly true for cases where distributed heat loads are being collected and funneled into a concentrated thermal interface to be transferred to the heat rejection system.

Known methods for coupling an OHP to the OHP heat rejection system (e.g., heat sink) typically involve the use of a mechanical interface filled with a gap filler of some sort, e.g., either a thermal grease or other specifically designed pad. In the case of thermal grease, a very thin interface is usually achievable leading to good conductance through the interface, however, grease is often not an option due to its tendency to migrate onto surfaces that must remain clean. The use of gap fillers and gap pads mitigates this risk, but produce larger gaps and lower thermal conductivities that lead to higher interface resistance and consequently higher operating temperatures. In various instances the heat sinks were often a pumped fluid circuits (PFCs) where it is required to couple the OHP to not only the heat source (e.g., electronics) but also to the PFC. However, thermally and physically coupling an OHP device to a PFC heat sink adds size and weight to the comprehensive device.

### SUMMARY

In various embodiments, a core concept of present disclosure is an OHP device with one or more OHP circuits conducting heat from heat input regions and transferring the heat to heat rejection regions that contain one or more pumped fluid circuit containing inlets and outlets such that a cooling fluid (single or multi-phase) can be supplied from an external cooling circuit. More particularly, the present disclosure provides integrating one or more OHP circuit with one or more pumped fluid circuit in a single monolithic device, thereby improving the efficiency of OHP devices. Utilizing any of various manufacturing processes such as milling, multilayer construction, additive manufacturing (e.g., 3D printing), one or more pumped fluid circuits can be integrally formed, layered, nested, intertwined, etc. with, through, adjacent and/or around one or more OHP circuit in a in a single monolithic device.

Additionally, in various embodiments, the present disclosure provides a method of fin formation within the OHP channels of an OHP device that is especially useful for OHP devices that are used to transform a heat flux from high concentration to low concentration, before being rejected to a heat sink. In such embodiments, using small-scale fin structures selectively located within the evaporator and/or the condenser regions only of the OHP channels can be used to reduce the thermal resistance in the region where the heat flux is the highest, often by an order of magnitude or more. This leads to a higher heat spreading capability and overall reduced source temperature, thereby improving the efficiency of OHP device by reducing the key thermal resistances at the working fluid and OHP channel wall interfaces. This reduces the source temperature and ultimately leads to longer life and higher reliability of the heat generating device the OHP device is being used to cool.

This summary is provided merely for purposes of summarizing various example embodiments of the present disclosure so as to provide a basic understanding of various aspects of the teachings herein. Various embodiments, aspects, and advantages will become apparent from the following detailed description taken in conjunction with the accompanying drawings which illustrate, by way of example, the principles of the described embodiments. Accordingly, it should be understood that the description and specific examples set forth herein are intended for purposes of illustration only and are not intended to limit the scope of the present teachings.

### DRAWINGS

The drawings described herein are for illustration purposes only and are not intended to limit the scope of the present teachings in any way.

FIG. 1 is an exemplary block diagram of a monolithic oscillating heat pipe (OHP) device, in accordance with various embodiments of the present disclosure.

FIG. 2A is cross-sectional view of at least a portion of the monolithic OHP device shown in FIGS. 1 and 2B having a layered architecture with one or more OHP circuit layer and one or more pumped fluid (PF) circuit layer, in accordance with various embodiments of the present disclosure

FIG. 2B is a top view block diagram of the embodiments of the monolithic OHP device shown in FIGS. 1, 2A and 2C, in accordance with various embodiments of the present disclosure.

FIG. 2C is cross-sectional view of at least a portion of the monolithic OHP device shown in FIGS. 1 and 2B having a layered architecture with one or more OHP circuit layer and one or more pumped fluid (PF) circuit layer, in accordance with various other embodiments of the present disclosure.

FIG. 3A is cross-sectional view of at least a portion of the monolithic OHP device shown in FIGS. 1 and 3B having cavity and duct configuration, in accordance with various embodiments of the present disclosure.

FIG. 3B is a top view block diagram of the embodiments of the monolithic OHP device shown in FIGS. 1, 3A and 3C, in accordance with various embodiments of the present disclosure.

FIG. 3C is cross-sectional view of at least a portion of the monolithic OHP device shown in FIGS. 1 and 3B having cavity and duct configuration, in accordance with various other embodiments of the present disclosure.

FIG. 3D is cross-sectional view of at least a portion of the monolithic OHP device shown in FIGS. 1 and 3B having cavity and duct configuration, in accordance with yet other exemplary embodiments of the present disclosure.

FIG. 4A is cross-sectional view of at least a portion of the monolithic OHP device shown in FIGS. 1 and 4B having side-by-side configuration, in accordance with various embodiments of the present disclosure.

FIG. 4B is a top cross-sectional view of at least a portion of the embodiments of the monolithic OHP device shown in FIGS. 1 and 4A, in accordance with various embodiments of the present disclosure.

FIG. 5A is cross-sectional view of at least a portion of the monolithic OHP device shown in FIGS. 1 having coplanar configuration, in accordance with various embodiments of the present disclosure.

FIG. 5B is cross-sectional view of the monolithic OHP device shown in FIGS. 1 having coplanar configuration, in accordance with various other embodiments of the present disclosure.

FIG. 6 is a cross-section of at least a portion of the monolithic OHP device shown in FIGS. 1 through 5B wherein the PF circuit comprises a plurality of conduits that include one or more internal fin to improve heat transfer from the OHP circuit into the PF circuit, in accordance with various embodiments of the present disclosure.

FIG. 7A is a cross-section of at least a portion of the monolithic OHP device shown in FIGS. 1 through 6, wherein the OHP channels include one or more internal fin to improve heat transfer from the heat source(s) into the OHP circuit, in accordance with various embodiments of the present disclosure.

FIG. 7B is a cross-sectional view of a portion of an OHP device having the internal fins formed within the OHP channels only at heat source locations of the OHP device, in accordance with various embodiments of the present disclosure.

FIG. 8 is an exploded view of an OHP device comprising the internal fins formed within the OHP channels that is fabricated having the fins formed on a lid that is hermetically sealed to a lower body comprising the OHP channels, in accordance with various embodiments of the present disclosure.

Corresponding reference numerals indicate corresponding parts throughout the several views of drawings.

### DETAILED DESCRIPTION

The following description is merely exemplary in nature and is in no way intended to limit the present teachings, application, or uses. Throughout this specification, like reference numerals will be used to refer to like elements. Additionally, the embodiments disclosed below are not intended to be exhaustive or to limit the invention to the precise forms disclosed in the following detailed description. Rather, the embodiments are chosen and described so that others skilled in the art can utilize their teachings. As well, it should be understood that the drawings are intended to illustrate and plainly disclose presently envisioned embodiments to one of skill in the art, but are not intended to be manufacturing level drawings or renditions of final products and may include simplified conceptual views to facilitate understanding or explanation. As well, the relative size and arrangement of the components may differ from that shown and still operate within the spirit of the invention.

As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to practice the disclosure and are not intended to limit the scope of the appended claims.

Unless otherwise defined, all technical and scientific terms used herein have the same meaning as commonly understood by one of ordinary skill in the art to which this disclosure belongs. The terminology used herein is for the purpose of describing particular example embodiments only and is not intended to be limiting. As used herein, the singular forms “a”, “an”, and “the” may be intended to include the plural forms as well, unless the context clearly indicates otherwise. The terms “comprises”, “comprising”, “including”, and “having” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps can be employed.

When an element, object, device, apparatus, component, region or section, etc., is referred to as being “on”, “engaged to or with”, “connected to or with”, or “coupled to or with” another element, object, device, apparatus, component, region or section, etc., it can be directly on, engaged, connected or coupled to or with the other element, object, device, apparatus, component, region or section, etc., or intervening elements, objects, devices, apparatuses, components, regions or sections, etc., can be present. In contrast, when an element, object, device, apparatus, component, region or section, etc., is referred to as being “directly on”, “directly engaged to”, “directly connected to”, or “directly coupled to” another element, object, device, apparatus, component, region or section, etc., there may be no intervening elements, objects, devices, apparatuses, components, regions or sections, etc., present. Other words used to describe the relationship between elements, objects, devices, apparatuses, components, regions or sections, etc., should be interpreted in a like fashion (e.g., “between” versus “directly between”, “adjacent” versus “directly adjacent”, etc.).

As used herein the phrase “operably connected to” will be understood to mean two are more elements, objects, devices, apparatuses, components, etc., that are directly or indirectly connected to each other in an operational and/or cooperative manner such that operation or function of at least one of the elements, objects, devices, apparatuses, components, etc., imparts are causes operation or function of at least one other of the elements, objects, devices, apparatuses, components, etc. Such imparting or causing of operation or function can be unilateral or bilateral.

As used herein, the term “and/or” includes any and all combinations of one or more of the associated listed items. For example, A and/or B includes A alone, or B alone, or both A and B.

Although the terms first, second, third, etc. can be used herein to describe various elements, objects, devices, apparatuses, components, regions or sections, etc., these elements, objects, devices, apparatuses, components, regions or sections, etc., should not be limited by these terms. These terms may be used only to distinguish one element, object, device, apparatus, component, region or section, etc., from another element, object, device, apparatus, component, region or section, etc., and do not necessarily imply a sequence or order unless clearly indicated by the context.

Moreover, it will be understood that various directions such as “upper”, “lower”, “bottom”, “top”, “left”, “right”, “first”, “second” and so forth are made only with respect to explanation in conjunction with the drawings, and that components may be oriented differently, for instance, during transportation and manufacturing as well as operation. Because many varying and different embodiments may be made within the scope of the concept(s) taught herein, and because many modifications may be made in the embodiments described herein, it is to be understood that the details herein are to be interpreted as illustrative and non-limiting.

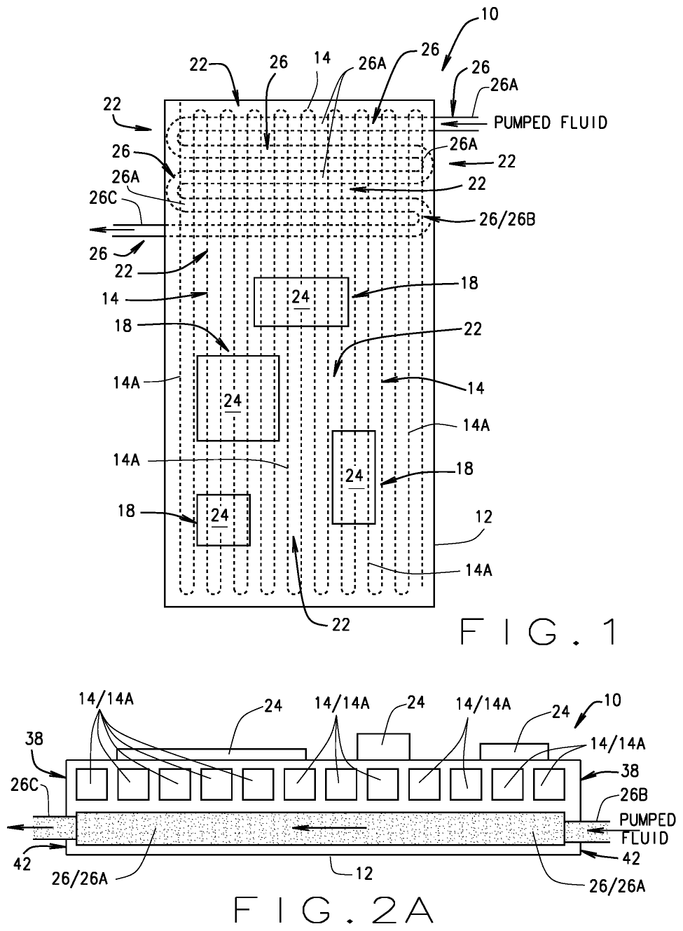

Referring to FIG. 1, the present disclosure generally provides a monolithic oscillating heat pipe (OHP) device 10 comprising a monolithic body 12 having one or more OHP circuit 14 integrally formed therein. The OHP circuit(s) 14 is/are structured and operable to conduct heat from one or more heat source regions 18 and isothermally spread the heat through the body 12 to one or more heat sink or rejection region 22. The heat source region(s) 18 is/are any region of the body 12 that is in thermally conductive and physical contact with one or more heat generating device 24, such as an electronic device (e.g., an integrated circuit semiconductor device) or other heat generating device that is provided, disposed, formed, or fabricated on the body 12. The monolithic OHP device 10 additionally comprises one or more of the heat rejection regions 22. The heat rejection regions 22 can be any region(s) of the body 12 that is/are not in physical contact with a heat generating device 24. The OHP circuit(s) 14 comprise one or more multi-pass meandering, hermetically sealed capillary channel 14A (e.g., micro-channel) integrally formed within the body 12 that cross the heat source and rejection regions 18 and 22 multiple times. The monolithic OHP device 10 further comprises one or more pumped fluid (PF) circuit 26 having a portion thereof integrally formed within at least a portion of the body 12. Particularly, each PF circuit 26 comprises one or more heat exchange portions 26A that is/are integrally formed within at least a portion of the body 12 such that PF circuit heat exchange portion(s) 26A is/are in thermally conductive contact with at least a portion of the OHP circuit(s) 14. More specifically, the PF circuit heat exchange portion(s) 26A is/are integrally formed, layered, nested, intertwined, etc. around, near or adjacent at least a portion of the OHP circuit(s) 14.

Additionally, each PF circuit 26 comprises at least one inlet 26B fluidly connected to the PF circuit heat exchange portion(s) 26A, and at least one outlet 26C fluidly connected to the PF circuit heat exchange portion(s) 26A. The inlet(s) 26B and outlet(s) 26C are structured and operable to allow a cooling fluid or gas (single-phase, two-phase or multi-phase) to be supplied from an external cooling fluid source (not shown) pumped and circulated through the PF circuit heat exchange portion(s) 26A, via pump (not shown), and returned to the external coiling fluid source. The PF circuit(s) 26 cooling fluid/gas can be any desired single-phase, two-phase or multi-phase fluid/gas such as water, deionized water, glycol/water solutions, and dielectric fluids such as fluorocarbons that are not corrosive to the respective material used to provide the body 12. In various instances, the PF circuit(s) 26 cooling fluid/gas can be pre-cooled or refrigerated prior to being pumped through the PF circuit(s) 26. Each PF circuit heat exchange portion 26A can be structured to comprise one or more lumen, conduit, ducts, tunnel, passage, cavity and/or chamber integrally formed within the body 12, and can have any desired shape, size, configuration, design and/or path through the body 12. For example, in various instances, the PF circuit heat exchange portion(s) 26A is/are integrally formed within the body to have a maximum heat transfer per mass flow with minimal pressure drop. For example, in various instances it is advantageous to integrally form the PF circuit heat exchange portion(s) 26A within the body 12 to be straight, and/or comprise large conduits/ducts/tunnels/passages/cavities/chambers relative to the size dimension of OHP channels 14A of the OHP circuit(s)14, or by generally keeping the layout pattern of the PF circuit heat exchange portion(s) 26A conduits/ducts/tunnels/passages/cavities/chambers simple such that they present minimal impedance and restriction to the flow of the cooling fluid/gas through the PF circuit heat exchange portion(s) conduits/ducts/tunnels/passages/cavities/chambers.

The OHP channel(s) 14A is/are filled with a saturated two-phase working fluid that, due to the channel diameter and fluid properties, forms a train of liquid plugs and vapor bubbles. When heat from the heat generating device(s) 24 is absorbed by the fluid in the OHP channels 14A, the resulting evaporation and condensation processes create pressure imbalances that, coupled with the random distribution of liquid plugs and vapor bubbles, generates motion of the two-phase mixture. As described above, the PF circuit heat exchange portion(s) 26A comprises one or more internal lumen, conduit, ducts, tunnel, passage, cavity and/or chamber having any shape or design that is integrally formed, layered, nested, intertwined, etc. around, near or adjacent at least a portion of the OHP circuit(s) 14.

More specifically, since the OHP channel(s) 14A are integrally formed within the body 12 on which the heat generating device(s) 24 are provided, disposed, formed, or fabricated, the OHP channel(s) 14A pass near and/or adjacent and in close proximity (e.g., within approximately tens to hundreds of microns) to the heat generating devices 24. The capillary dimensions of the OHP channel(s) 14A (e.g., from hundreds of nanometers to hundreds of microns) force the working fluid into the train of liquid plugs and vapor bubbles. As heat is absorbed from the heat generating device(s) 24 by the working fluid within the OHP channel(s) 14A, evaporation and condensation of the working fluid occurs that cause a pressure imbalance from the heat source region 18 (i.e., evaporator region(s)) of the OHP channel(s) 14A to the heat rejection region(s) 22 (i.e., condenser region(s)) of the OHP channel(s) 14A. As described above, heat source region 18 (i.e., evaporator region(s)) of the OHP channel(s) 14A are the regions of OHP channel(s) 14A that pass within the body 12 near and/or adjacent and close proximity to one or more of the heat generating device(s) 24. The heat rejection region(s) 22 (i.e., condenser region(s)) of the OHP channel(s) 14A are the regions of the OHP channel(s) 14A that pass within the body 12 near and/or adjacent a region of the body 12 not occupied by a heat generating device(s) 24 and/or near and/or adjacent and/or in close proximity to and in thermally conductive contact with one or more of the PF circuit 26 (e.g., thermally conductive contact with one or more PF circuit heat exchange portion 26A). For example, regions of the OHP channel(s) 14A that pass within the body 12 near and/or adjacent a region of a top surface, bottom surface, or other surface of the body 12 that is not occupied by a heat generating device(s) 24 and exposed to ambient air, and/or is/are in thermally conductive contact with one or more PF circuit heat exchange portion 26A (as exemplarily and generically shown in FIG. 1).

This pressure imbalance forces the working fluid to move within the OHP channel(s) 14A, transferring heat (e.g., both latent and sensible heat) from the heat source region(s) 18 (e.g., evaporation portion(s)) of the OHP channel(s) 14A to the heat rejection region(s) 22 (e.g., condenser portion(s)) of the OHP channel(s) 14A, thereby removing heat from, and cooling, the respective heat generating devices 24, and the monolithic OHP device 10 overall. More specifically, when heat is absorbed at the heat source region(s) 18 of the OHP channel(s) 14A, bubbles are formed by partial vaporization of the working fluid within the channels 14A in the heat source region(s) 18. The bubble's expansion is limited radially by the fixed diameter of the OHP channel(s) 14A and thus, the bubble expands axially (i.e., along the length of the OHP channel 14A). The axial-wise expansion dislodges neighboring plugs/bubbles in a first portion of the OHP channel(s) 14A and forced them away from the heat source region(s) 18. The dislodged vapor phase working fluid moves through the OHP channel(s) 14A to the heat rejection region(s) 22 where the heat of the vapor phase working fluid is rejected into the ambient air and/or to the FP circuit 26 (e.g., to the FP circuit heat exchange region(s) 26A) such that the vapor phase working fluid converts back to liquid phase. The PF circuit(s) 26 greatly increase the removal of heat (thermal energy) from the heat rejection portions of OHP channel(s) 14A that are in thermally conductive contact with the PF circuit(s) 26. Hence, the PF circuit heat exchange portion(s) 26A integrated along with the OHP circuit(s) 14 within the body 12 greatly increases heat removal from the heat generating device(s) 24 and the monolithic OHP device 10 overall. As described above, while in the heat rejection region(s) 22 of the OHP channel(s) 14A, the vapor phase working fluid is cooled and converts back to the liquid phase plug, which then moves back to the heat source region(s) 18 of the OHP channel(s) 14A to repeat the vaporization-condensation cycle to continuously remove heat from, and cool, the respective heat generating device(s) 24, and the monolithic OHP device 10 overall.

The pattern of OHP channel(s) 14A can form a closed-loop (e.g. circulating), or they can be sealed at each end to form an open-loop (e.g. serpentine or linear). Furthermore, pattern of OHP channel(s) 14A can travel in two dimensions (i.e. in x-y plane if in a body-like pattern, or in a disk-like pattern in the r-θ plane) or in all three physical dimensions (i.e. x-y-z and/or r-θ-h). Channel 14A cross-sections can be effective in many shapes (e.g., circular, semi-circle, rectangle, square, etc.) and tunnel lengths can vary (e.g., from less than 50 cm to greater than 1 m) so long as they maintain the capillary effect where the working fluid inside the channel volume is dispersed in discrete liquid “plugs” and vapor “bubbles”. Generally, the closer packed the channels 14A are (and the greater the number of turns in the meandering channel pattern) the better the thermal performance of the monolithic OHP device 10. The working fluid can be any desired working fluid selected based on its thermophysical properties (e.g. vapor pressures, latent heats, specific heats, densities, surface tensions, critical temperatures, pour points, viscosities, etc.) and compatible with the material(s) used to form the body 12 and channels 14A.

The monolithic OHP device 10, can be made from a wide range of material and fluid combinations and in a variety of shapes and sizes in order to meet the specifications of a given application's heat source(s) and heat sink(s) or rejection regions(s) (e.g. their sizes, heat loads, heat fluxes, locations, temperatures, gravitational fields, coefficients of thermal expansion requirements, etc.). More particularly, the monolithic OHP device 10 (e.g., the body 12, the integrally formed OHP circuit(s) 14, and the integrally formed PF circuit heat exchange portion(s) 26A) can be formed using any desired manufacturing or fabrication process including, but not limited to: forming the OHP channels 14A and PF circuit heat exchange portion(s) 26A on or through a flat body substrate using bulk micromachining, surface micromachining, deep reactive ion etching, LIGA (lithography, electroplating, and molding), hot embossing, micro-EDM (electrical discharge machining), XeF2 Dry Phase Etching, focused ion beam micromachining, CVD (chemical vapor deposition), and/or PVD (physical vapor deposition) and then sealing those channels 14A with a lid or cover; laminating brazing or diffusion boding multiple layers together, or utilizing additive manufacturing techniques to inherently form the channels 14A and PF circuit heat exchange portion(s) 26A within the solid body 12 (e.g. 3D-printing, direct metal laser sintering/melting, stereo lithography, ultrasonic additive manufacturing, electron beam freeform fabrication, etc.), or any other suitable known or unknow manufacturing or fabricating process.

By integrating the PF circuit(s) 26 (e.g., the PF circuit heat exchange portions 26A) into the same monolithic OHP device 10 as the OHP circuit(s) 14, at least one thermal interface of known OHP devices can be removed, thereby eliminating the corresponding thermal gradient at that interface.

As described above, the heat exchange portion(s) 26A of the PF circuit(s) 26 are integrally formed within at least of a portion the body 12 and is/are in thermally conductive contact with the OHP circuit(s) 14. Hence, the PF circuit heat exchange portion(s) 26A can be integrally formed within a small portion of the body 12, a large portion of the body, or substantially the entire body 12. More particularly, the OHP circuits 14 and PF circuits 26 can be integrally formed within the body 12 of the monolithic OHP device 10 having any desired thermally conductive positional relation with each other such that one or more PF circuits 26 are integrally formed, layered, nested, intertwined, etc., with, through, adjacent and/or around one or more OHP circuit 14 internally within the body 12.

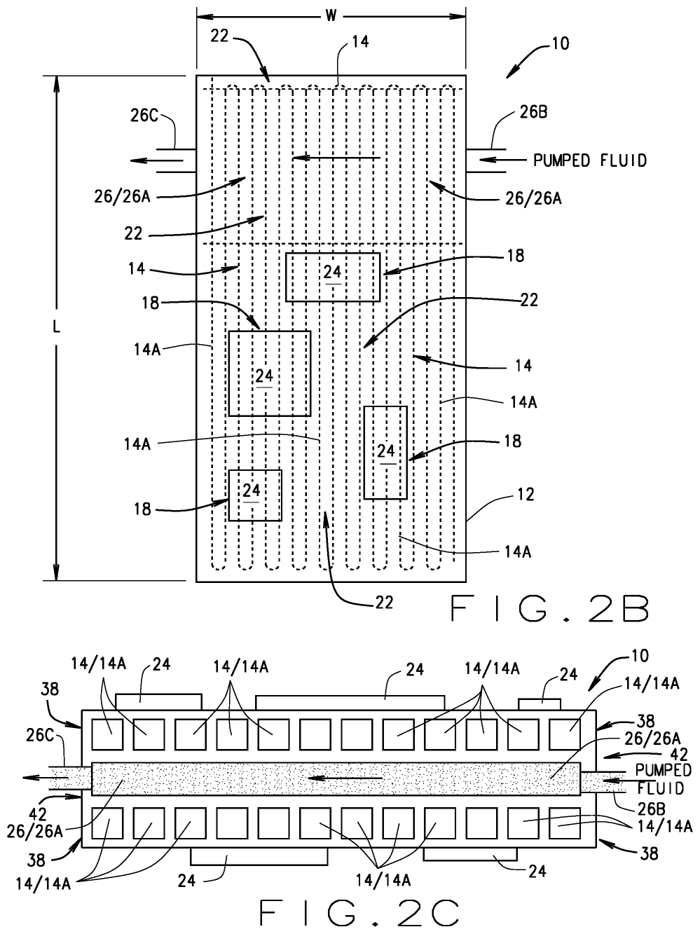

For example, referring now to FIGS. 2A 2B and 2C, in various embodiments, the monolithic OHP device 10 can have a layered configuration wherein the OHP circuit(s) 14 and channels 14A are integrally formed within at least one planar OHP circuit layer 38 of the body 12, and the PF circuit(s) 26 (e.g., the PF circuit heat exchange portion(s) 26A) are integrally formed within at least one planar PF circuit layer 42 that is disposed above, below or in between the planar OHP circuit layer(s) 38. In various instances of such embodiments, the OHP circuit layer(s) 38 and PF circuit layer(s) 42 separately formed and bonded together via lamination, brazing, diffusion bonding or other bonding method or means, to form the monolithic body 12. In other embodiments, the monolithic body 12 can be fabricated as a unibody via additive manufacturing or other methods and means described herein. In such embodiments, the OHP circuit(s) 14 and channels 14A can be formed, disposed, patterned and/or arrayed throughout any portion of, or an entire planar area of, the respective OHP circuit layer 38 defined by a length L and a width W of the body 12. Similarly, in such embodiments, the PF circuit(s) 26 (e.g., the PF circuit heat exchange portion(s) 26A) can be formed, disposed, patterned and/or arrayed throughout any portion of, or an entire planar area of the respective PF circuit layer 42 defined by the length L and the width W of the body 12. In various instances of such embodiments, a very thin layer of material separates the PF circuit heat exchange portion(s) 26A from the OHP circuit(s) 14 (without risk of leaks) such that a high rate of thermal energy can be exchanged between the working fluid flowing within the OHP channels 14A and the pumped cooling fluid flowing through the PF circuit(s) 26. Furthermore, in various instances, the PF circuit 26 (e.g., heat exchange cavity 26A) can be structured to have inlet and outlet 26B and 26C formed and disposed within opposing longitudinal sides (e.g., side having the length L) such that the flow of the pumped fluid is lateral to the OHP circuit channels 14A. Alternatively, in other instances the PF circuit 26 (e.g., heat exchange cavity 26A) can be structured to have inlet and outlet 26B and 26C formed and disposed within opposing lateral sides (e.g., side having the width W) such that the flow of the pumped fluid is parallel with the OHP circuit channels 14A.

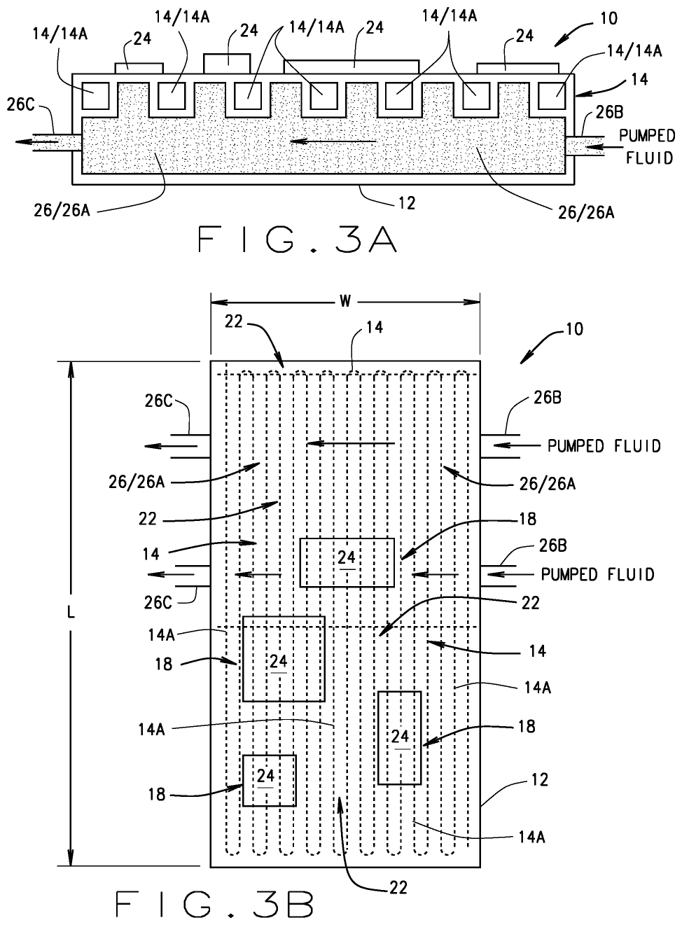

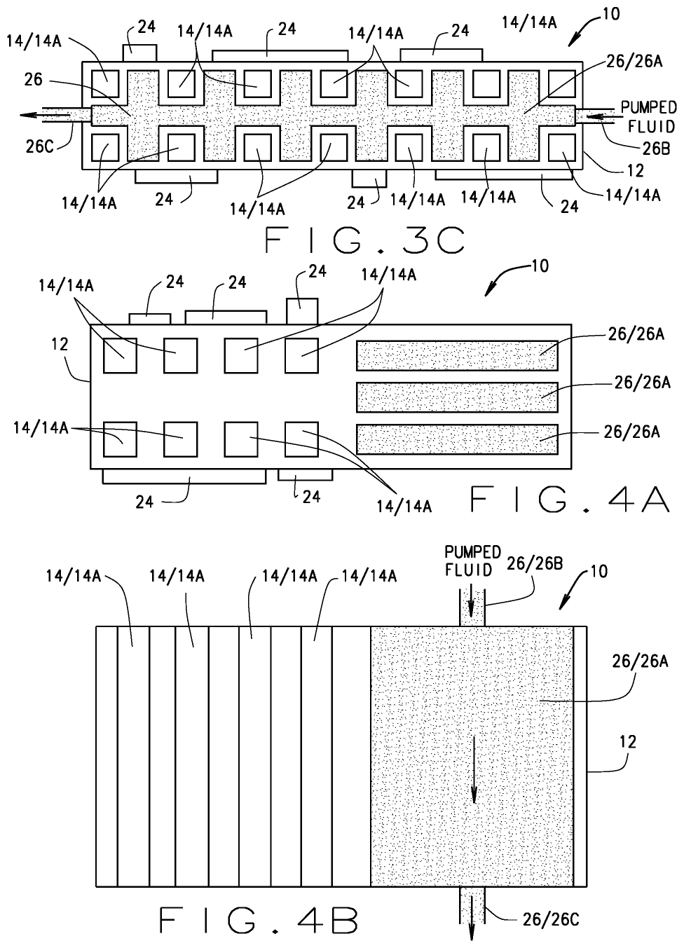

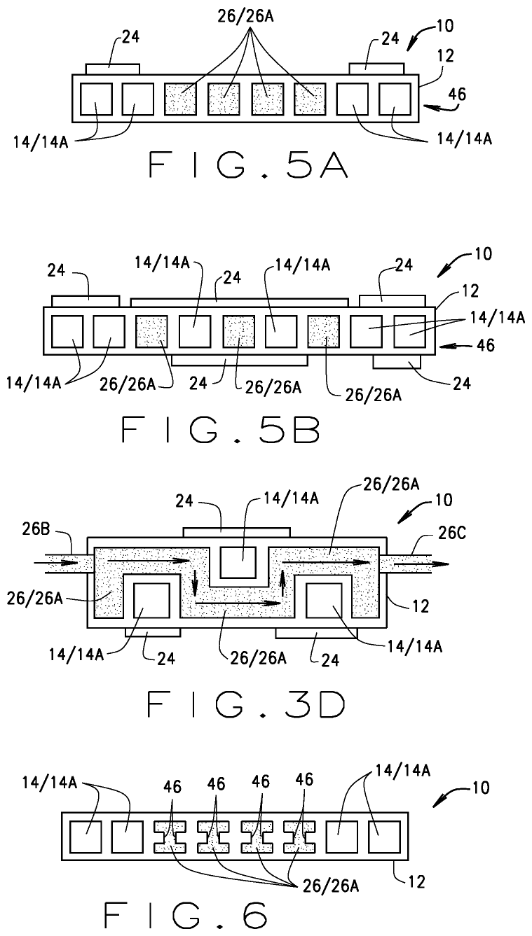

Referring now to FIGS. 3A, 3B, 3C and 3D, in various other exemplary embodiments, the monolithic OHP device 10 can have a cavity and duct configuration wherein the OHP circuit(s) 14 and channels 14A are integrally formed within the body 12 to extend and protrude into a PF circuit heat exchange portion 26A integrally formed within the body 12 as a cavity. Therefore, in such embodiments, the pumped fluid circulating through the PF circuit heat exchange cavity 26A directly contacts the exterior surface of the wall(s) of the OHP circuit channels 14A, and moreover directly contacts a large surface area of the exterior surface of the OHP channel 14A wall(s). For example, 60%-90% of the surface area of the OHP channel 14A wall(s) can be exposed to and in direct contact with the pumped fluid circulating through the PF circuit heat exchange cavity 26A, thereby improving/increasing heat transfer from the OHP circuit channel(s) 14A into the PF circuit heat exchange portion conduits 26A. In such embodiments, the OHP circuit(s) 14 and channels 14A can be formed, disposed, patterned and/or arrayed throughout any portion of, or an entire planar area of, the body 12 defined by the length L and the width W of the body 12. Similarly, in such embodiments, the PF circuit heat exchange 26A cavity can be formed, disposed, within any portion of, or an entire planar area, of the body 12 defined by the length L and the width W of the body 12. Furthermore, in various instances, the PF circuit 26 (e.g., heat exchange cavity 26A) can be structured to have inlet and outlet 26B and 26C formed and disposed within opposing longitudinal sides (e.g., side having the length L) such that the flow of the pumped fluid is lateral to the OHP circuit channels 14A. Alternatively, in other instances the PF circuit 26 (e.g., heat exchange cavity 26A) can be structured to have inlet and outlet 26B and 26C formed and disposed within opposing lateral sides (e.g., side having the width W) such that the flow of the pumped fluid is parallel with the OHP circuit channels 14A.

Referring now to FIGS. 4A and 4B, in further various exemplary embodiments, the monolithic OHP device 10 can have a OHP circuit 14 and PF circuit 26 side-by-side configuration. In such embodiments, the OHP circuit channels 14A are integrally formed within a first portion of the body 12 and the PF circuit heat exchange portion(s) 26A is/are integrally formed within a second portion of the body 12 that is independent from and laterally adjacent to the first portion such that the first and second portions of the body 12, and hence the OHP circuit channels 14A and the PC circuit heat exchange portion(s) 26A, have a side-by-side positional relationship.

Referring now to FIGS. 5A and 5B, in further yet various exemplary embodiments, the monolithic OHP device 10 can have a OHP circuit 14 and PF circuit 26 a layered coplanar configuration. In such embodiments, the OHP circuit channels 14A and FP circuit heat exchange portion(s) 26A are integrally formed within the body 12 in a coplanar positional relationship within each of one or more planar layers 46. In such embodiments, the monolithic OHP device 10 can comprise one or more planar layer 46, wherein each layer 46 includes both the OHP circuit channels 14A and the FP circuit heat exchange portion(s) 26A nested with and/or intertwined with, and adjacent each other in any desired array or pattern.

Referring now to FIG. 6, in various embodiments, the monolithic OHP device 10 can include the PF circuit heat exchange portion 26A comprising a plurality of interconnected conduits. Additionally, in various instances of such embodiments, one or more of the PF circuit heat exchange portion conduits 26A can include one or more internal fin 50 extending, and protruding radially inward, from an interior of the wall of the respective PF circuit heat exchange portion conduit(s) 26A. The fin(s) 50 increase the interior surface area of the wall(s) of the PF circuit heat exchange portion conduits 26A, thereby improving/increasing heat transfer from the OHP circuit 14 into the PF circuit heat exchange portion conduits 26A.

Referring now to FIGS. 1 through 6, although the monolithic OHP device 10 has been described above with regard to various exemplary embodiments, it should be understood that it is envisioned that the monolithic OHP device 10 can be fabricated, manufactured, formed or otherwise constructed to comprise, in form and function, any combination of any two or more of the above described exemplary embodiments. Additionally, as described above, any and all of the above described exemplary embodiments, or combinations thereof, of the monolithic OHP device 10 can be fabricated, manufactured, formed or otherwise constructed using any desired and applicable manufacturing or fabrication process. For example, the body 12 and the OHP channels 14A and PF circuit heat exchange portion(s) 26A integrally formed within the body 12 can be manufactured or fabricated using bulk micromachining, surface micromachining, deep reactive ion etching, LIGA (lithography, electroplating, and molding), hot embossing, micro-EDM (electrical discharge machining), XeF2 Dry Phase Etching, focused ion beam micromachining, CVD (chemical vapor deposition), and/or PVD (physical vapor deposition) and then sealing those channels 14A with a lid or cover; laminating, brazing or diffusion boding multiple layers together, or utilizing additive manufacturing techniques to inherently form the channels 14A and PF circuit heat exchange portion(s) 26A within the solid body 12 (e.g. 3D-printing, direct metal laser sintering/melting, stereo lithography, ultrasonic additive manufacturing, electron beam freeform fabrication, etc.), or any other suitable known or unknow manufacturing or fabricating process.

By integrating PF circuit(s) 26 into the body 12 of monolithic OHP device 10 along with the OHP circuit(s) 14 provides the opportunity for mass and size optimization of the overall monolithic OHP device 10 by utilizing the volume within the monolithic OHP device 10 that would otherwise not be utilized. Furthermore, integrating the PF circuit(s) 26 and OHP circuit(s) 14 into a single structure (e.g., the body 12) allows for further system optimization by allowing the PF circuit(s) 26 to be optimized to reduce pressure drop and relying on the OHP channels 14A to help gather and deliver heat over a broader area to the PF circuit(s) 26.

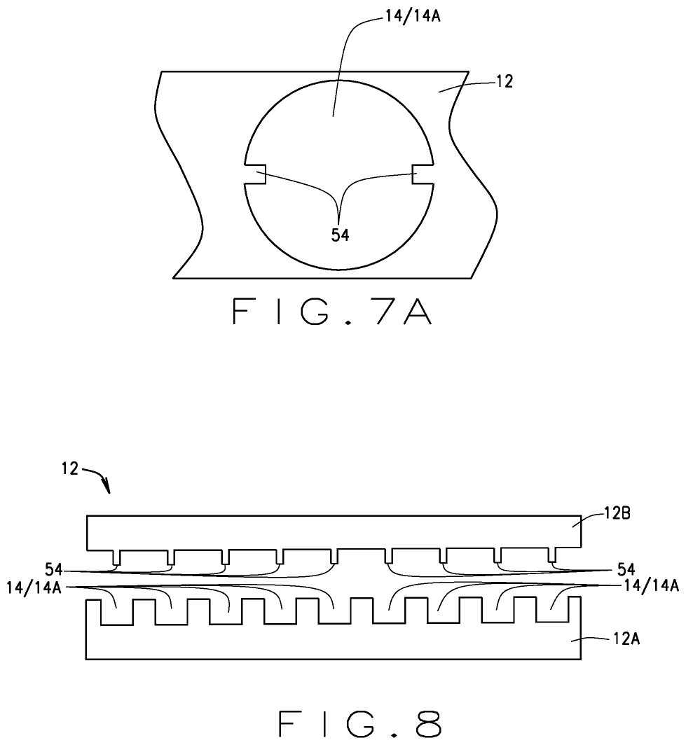

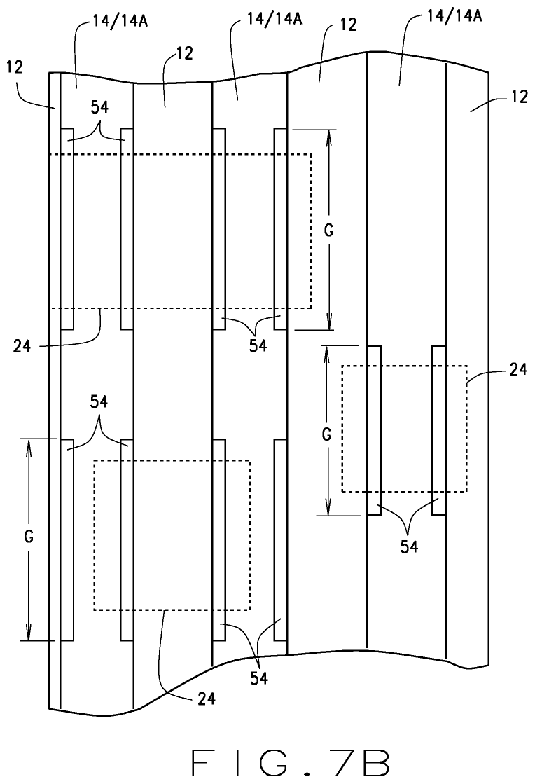

Referring now to FIGS. 7A and 7B, as described above OHPs are often employed in applications where pure conduction, natural convection or radiation are insufficient to maintain electronics temperatures at low enough temperatures to promote long term reliability. Improving the efficiency of OHP devices can be accomplished by reducing the key thermal resistances at the working fluid and wall interfaces. This reduces the source temperature and ultimately leads to longer life and higher reliability of the heat generating device the OHP device is being used to cool. Therefore, in various embodiments, the present disclosure provides an OHP circuit (for example, any or all of the exemplary embodiments of OHP circuits 14 described above and exemplarily illustrated in FIGS. 1-6), wherein the OHP channels (for example any or all of the exemplary embodiments of OHP circuit channel(s) 14A described above and exemplarily illustrated in FIGS. 1-6) comprise one or more internal fin 54 extending, and protruding radially inward, from an at least a portion of an interior of the wall of the OHP channel. The formation of the fins within the OHP channels is especially useful for OHP devices that are used to transform a heat flux from high concentration to low concentration, before being rejected to a heat sink (e.g., the PF circuit 26).

Although it should be understood that the OHP channel fins 54 can be formed and implemented in the OHP channels of any OHP device, for simplicity and clarity, the OHP channel fins 54 and the OHP devices comprising the OHP channel fins 54 will be exemplarily described and illustrated herein with reference to the monolithic OHP device 10 and the OHP circuit channels 14A.

Hence, FIG. 7A exemplarily illustrates a lateral end view cross-section of a portion of the body 12 of the monolithic OHP device 10 including a single OHP channel 14A of an OHP circuit 14. FIG. 7B exemplarily illustrates longitudinal top view cross-section of a portion of the body 12 of the monolithic OHP device 10 including a plurality OHP channels 14A of an OHP circuit 14 having a plurality of heat generating devices 24 disposed thereon. The heat transport for the OHP channels 14A and OHP circuit(s) 14 depends largely on the working fluid velocity flowing through the OHP channels 14A and the amount of directly heated area of the body 12 (e.g., the area of the body 12 in physical and thermally conductive contact with the heat generating source(s) 24) that is internally directly and thermally contacted by the working fluid flowing through the OHP channels 14A. To enhance the two-phase heat transfer efficiency, in various embodiments one or more of the OHP circuit channels 14A can comprise one or more fins 54 extending and protruding radially inward from an interior wall of the respective OHP circuit channel(s) 14A. Adding the fins 54 effectively increases surface area of the OHP channels 14A that are directly and thermally contacted by the working fluid. This increase in OHP channel surface area contacted by the working fluid increases the turbulence within the OHP channels 14A and decreases the thermal resistance at the interface of the working fluid and the wall(s) of the OHP channels 14A. This in turn increases the heat transfer coefficient between the working fluid and the interior surface of the OHP channels 14A, resulting in greater thermal power out per unit mass flow. The fin(s) 54 are formed longitudinally along the length of the OHP channel(s) 14A. More specifically, the fin(s) 54 can be formed along any longitudinal portion of, or the entire length, of the OHP channel 14A wall, and can be formed in any or all of the OHP channels 14A of an OHP circuit 14.

However, it is envisioned that having the fins 54 formed too densely or too long in length within the OHP channels 14A can restrict the flow of the working fluid due to the pressure drop of the two-phase flow. Therefore, in various embodiments, as exemplarily illustrated in FIG. 7B, at least some (or all) the fins 54 have a selected length G and are located in selected regions of the OHP channels 14A, while other regions of the OHP channels 14A do not include the fins 54 so as to provide a larger flow cross section in such regions. For example, in various embodiments, at least one (e.g., a plurality or all) of the fins 54 are selectively located within the evaporator regions only of the OHP channels 14A. That is, fins 54 are selectively located within only the portions of the OHP channels 14A formed within the body 12 directly adjacent the heat generating devices 24. The length G of the fins 54 can vary from one fin 54 to the next fin 54 based on the size dimensions of the respective evaporator region within which the respective fin 54 is disposed. Hence, in such embodiments, the fins 54 are formed within the OHP channels 14A in critical heated areas while maintaining optimal flow cross sectional area in adiabatic areas. By selectively locating the fins 54 within the evaporator regions only of the OHP channels 14A, the thermal resistance in the region of the body 12 where the heat flux is the highest is significantly reduced (e.g., reduced by an order of magnitude or more). This leads to a higher heat spreading capability of the monolithic OHP device 10, which results in greater reduction of temperature of the heat generating devices 24.

Again, as described above, the monolithic OHP device 10 can be fabricated, manufactured, formed or otherwise constructed using any desired and applicable manufacturing or fabrication process. Accordingly, the monolithic OHP device 10 (or any other OHP device) comprising OHP channels 14A including the fins 54 can be fabricated, manufactured, formed or otherwise constructed using any desired and applicable manufacturing or fabrication process. For example, the body 12 and the OHP channels 14A integrally formed within the body 12 can be manufactured or fabricated using bulk micromachining, surface micromachining, deep reactive ion etching, LIGA (lithography, electroplating, and molding), hot embossing, micro-EDM (electrical discharge machining), XeF2 Dry Phase Etching, focused ion beam micromachining, CVD (chemical vapor deposition), and/or PVD (physical vapor deposition) and then sealing those channels 14A with a lid or cover; laminating, brazing or diffusion boding multiple layers together, or utilizing additive manufacturing techniques to inherently form the channels 14A and PF circuit heat exchange portion(s) 26A within the solid body 12 (e.g. 3D-printing, direct metal laser sintering/melting, stereo lithography, ultrasonic additive manufacturing, electron beam freeform fabrication, etc.), or any other suitable known or unknow manufacturing or fabricating process.

In an exemplary embodiment, it is envisioned that combining a planar lower body 12A with one or more planar lid plate 12B can an effective way to fabricate the monolithic OHP device 10 (or any other OHP device). In such instances, the fins 54 can be formed on and protrude from the lid plate 12B, and the OHP channels 14A can be formed in the lower body 12A. Subsequently, the OHP device can be assembled so that the fins 54 are inserted into the OHP channels 14A when the lid plate(s) 12B is connected to the lower body 12A. More specifically, the protruding fins 54 are inserted into the OHP channels 14A and the lid plate(s) is/are connected to the lower body 12A in a precise manner. For example, the protruding fins 54 can positioned downward precisely at the center of OHP channels 14A, and lid plate(s) 12B is/are precision aligned on the lower body 12A, whereafter the lid plate(s) 12B are bonded (e.g., hermetically sealed) to the lower body 12A using a bonding method such as, but not limited to, diffusion bonding or brazing. It is envisioned that the fins 54 can be formed in any location with respect to a two-dimensional channel pattern. It is envisioned that, in various instances, by disposing/forming/machining the fins 54 on the lid plate(s) 12B, the aspect ratio associated with the fin forming process, can be kept relatively low compared to forming the fins 54 within the OHP channels 14A. This process also does not significantly increase the complexity of the bonding or sealing process, except to require precision alignment lid plate(s) 12B with the lower body 12A.

Additionally, it is envisioned that, in various other embodiments, multiple OHP channel bodies, such as the lower body 12A, can have the fins 54 formed on the inside or outer surfaces thereof, and the multiple OHP channel bodies can be bonded (e.g., hermetically sealed) together to form the OHP device (e.g., the monolithic OHP device 10) having OHP channels 14A comprising the fins 54. Further yet, in various other embodiments, it is envisioned that horizontal fins 54 can be formed by constructing the OHP device (e.g., the monolithic OHP device 10) out of a plurality of layers, and selectively leaving fin surface area in key areas on specific layers.

It is envisioned that the channel architecture and design disclosed herein could be utilized to properly maintain heat generating device temperatures, especially electronics, for example, heat generating device aboard spacecraft where high reliability and long term life expectancy are paramount. By employing the heat spreader technology disclosed herein to cool electronics, optical heat generating devices, or any other heat generating device, cooler component temperatures and overall higher reliability will be realized, without the size, weight and power penalties, and cost constraints associated with other heat transfer device technologies.

The description herein is merely exemplary in nature and, thus, variations that do not depart from the gist of that which is described are intended to be within the scope of the teachings. Moreover, although the foregoing descriptions and the associated drawings describe example embodiments in the context of certain example combinations of elements and/or functions, it should be appreciated that different combinations of elements and/or functions can be provided by alternative embodiments without departing from the scope of the disclosure. Such variations and alternative combinations of elements and/or functions are not to be regarded as a departure from the spirit and scope of the teachings.

What is claimed is:

1. A monolithic oscillating heat pipe (OHP) device, said device comprising:
a monolithic body;
an oscillating heat pipe (OHP) circuit integrally formed within the body, the OHP circuit structured and operable to isothermally spread throughout the body heat from a heat source disposed on a heat source portion of the body and in thermally conductive contact with a portion of the OHP circuit; and
a pumped fluid (PF) circuit integrally formed within the body and in thermally conductive contact with at least portion of the OHP circuit internally within the body, the PF circuit structured and operable to remove heat from the portion of the OHP circuit in which the PF circuit is in thermally conductive contact with.

2. The monolithic OHP device of claim 1, wherein the OHP circuit comprises a plurality of channels integrally formed within the body that crosses the heat source regions multiple times.

3. The monolithic OHP device of claim 2, wherein the PF circuit comprises:
a heat exchange portion integrally formed within a portion of the body, wherein the heat exchange portion is in thermally conductive contact with the OHP circuit channels of at least a portion of the of the OHP circuit;
an inlet fluidly connected to the heat exchange portion; and
an outlet fluidly connected to the heat exchange portion.

4. The monolithic OHP device of claim 3 wherein the PF circuit heat exchange portion comprises:
at least one of:
a plurality lumens, and
at least one chamber.

5. The monolithic OHP device of claim 3, wherein the body comprises:
a planar OHP circuit layer comprising the OHP circuit integrally formed therein; and
a planar PF circuit layer comprising the PF circuit heat exchange portion integrally formed therein.

6. The monolithic OHP device of claim 3, wherein the PF circuit heat exchange portion is integrally formed within the body as a cavity and the OHP circuit channels are integrally formed within the body such that the OHP circuit channels extend and protrude into PF circuit heat exchange cavity.

7. The monolithic OHP device of claim 3, wherein the OHP circuit channels are integrally formed within a first portion of the body and the PF circuit heat exchange portion is integrally formed within a second portion of the body that is independent from and laterally adjacent to the first portion such that the OHP circuit channels and the PF circuit heat exchange portion have a side-by-side positional relationship.

8. The monolithic OHP device of claim 3, wherein monolithic body comprises one or more planar layer wherein each layer comprises both the OHP circuit channels and the PF circuit heat exchange portion are integrally formed therein having a coplanar positional relationship.

9. The monolithic OHP device of claim 3, wherein the PF circuit heat exchange portion comprises a plurality of interconnected conduits, wherein one or more of the conduits comprise one or more internal fin extending, and protruding radially inward, from an interior of a wall of the respective one or more conduit.

10. The monolithic OHP device of claim 3, wherein one or more of the OHP circuit channels comprise one or more internal fin extending, and protruding radially inward, from an interior of a wall of the respective one or more OHP circuit channel.

11. The monolithic OHP device of claim 10, wherein one or more of the OHP circuit channels comprise a plurality of the fins wherein the fins are disposed only in evaporator regions of the respective OHP circuit channels and have a selected length that is based on the size of the respective evaporator region.

12. A monolithic oscillating heat pipe (OHP) device, said device comprising:
a monolithic body;
an oscillating heat pipe (OHP) circuit integrally formed within the body and comprising a plurality of channels integrally formed within the body, the OHP circuit structured and operable to isothermally spread throughout the body heat from a heat source disposed on a heat source portion of the body and in thermally conductive contact with a portion of the OHP circuit; wherein the channels cross the heat source regions multiple times; and
a pumped fluid (PF) circuit structured and operable to remove heat from the OHP circuit, the PF circuit comprising:
a heat exchange portion integrally formed within a portion of the body and in thermally conductive contact with at least portion of the OHP circuit internally within the body, the heat exchange portion comprising at least one of:
a plurality lumens, and
at least one chamber,
an inlet fluidly connected to the heat exchange portion; and
an outlet fluidly connected to the heat exchange portion.

13. The monolithic OHP device of claim 12, wherein the body comprises:
a planar OHP circuit layer comprising the OHP circuit integrally formed therein; and
a planar PF circuit layer comprising the PF circuit heat exchange portion integrally formed therein.

14. The monolithic OHP device of claim 12, wherein the PF circuit heat exchange portion is integrally formed within the body as a cavity and the OHP circuit channels are integrally formed within the body such that the OHP circuit channels extend and protrude into PF circuit heat exchange cavity.

15. The monolithic OHP device of claim 12, wherein the OHP circuit channels are integrally formed within a first portion of the body and the PF circuit heat exchange portion is integrally formed within a second portion of the body that is independent from and laterally adjacent to the first portion such that the OHP circuit channels and the PF circuit heat exchange portion have a side-by-side positional relationship.

16. The monolithic OHP device of claim 12, wherein monolithic body comprises one or more planar layer wherein each layer comprises both the OHP circuit channels and the PF circuit heat exchange portion are integrally formed therein having a coplanar positional relationship.

17. The monolithic OHP device of claim 12, wherein the PF circuit heat exchange portion comprises a plurality of interconnected conduits, wherein one or more of the conduits comprise one or more internal fin extending, and protruding radially inward, from an interior of a wall of the respective one or more conduit.

18. The monolithic OHP device of claim 12, wherein one or more of the OHP circuit channels comprise one or more internal fin extending, and protruding radially inward, from an interior of a wall of the respective one or more OHP circuit channel.

19. The monolithic OHP device of claim 18, wherein one or more of the OHP circuit channels comprise a plurality of the fins wherein the fins are disposed only in evaporator regions of the respective OHP circuit channels and have a selected length that is based on the size of the respective evaporator region.

20. A oscillating heat pipe (OHP) device, said device comprising:
a body;
an oscillating heat pipe (OHP) circuit integrally formed within the body and comprising a plurality of channels integrally formed within the body, the OHP circuit structured and operable to isothermally spread throughout the body heat from a heat source disposed on a heat source portion of the body and in thermally conductive contact with a portion of the OHP circuit; wherein the channels cross the heat source regions multiple times; and
a plurality of internal fins extending, and protruding radially inward, from an interior of a wall of a plurality of the OHP circuit channels wherein the fins are disposed only in evaporator regions of the respective OHP circuit channels and have a selected length that is based on the size of the respective evaporator region.
